(19) United States
(12) Patent Application Publication
(10) Pub. No.: US 2006/0017118 A1
(43) Pub. Date: Jan. 26, 2006

(54) Semiconductor device having spacer pattern and method of forming the same

(76) Inventors: Je-Min Park, Suwon-si (KR); Yoo-Sang Hwang, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/184,855

(22) Filed: Jul. 20, 2005

(30) Foreign Application Priority Data
Jul. 21, 2004 (KR) 2004-56968

(51) Int. Cl. H01L 29/78; H01L 21/336

(52) U.S. Cl. 257/382; 438/305; 438/618; 257/408

(57) ABSTRACT

The present invention provides a semiconductor device having a spacer pattern and methods of forming the same that includes a lower interconnection pattern on a semiconductor substrate. A lower interconnection spacer covers sidewalls of the lower interconnection pattern. Spacer patterns cover the lower interconnection spacer of the lower interconnection pattern and disposed on the semiconductor substrate. An upper interconnection pattern is formed between the spacer patterns.

### BACKGROUND OF THE INVENTION

1. Field of the Invention

The present invention generally relates to a semiconductor device and methods of forming the same. More particularly, the present invention generally relates to a semiconductor device having a spacer pattern and methods of forming the same.

A claim of priority is made to Korean Patent Application No. 10-2004-0056968, filed Jul. 21, 2004, the contents of which are hereby incorporated by reference in their entirety.

2. Description of the Related Art

New semiconductor manufacturing apparatuses have been developed and used to manufacture semiconductor devices in order to adapt to the rapidly decreasing design rules. The new semiconductor manufacturing apparatuses are capable of producing pattern accurateness for discrete patterns on a photo mask or connection holes, which connects the discrete elements. The discrete elements include transistors, capacitors, and resistors. The connection holes are disposed in a predetermined portion on the discrete elements in an array form, and the connection holes expose the discrete elements. The discrete elements are connected to metal interconnections through the connection holes.

However, the size of the connection holes have gradually been reduced to meet design rules and to reduce production costs.

In general, a connection hole is formed using a photo mask with chromium (Cr) patterns. A photolithography process using the chromium (Cr) pattern has poor reproducibility. Thus, there is a photolithography process limitation using Cr patterns.

U.S. Pat. No. 6,252,267, in general discloses a five square folded-bitline DRAM cell.

The '267 patent discloses a DRAM cell having a gate stack and a trench capacitor. The trench capacitor has a trench filled with polysilicon. The gate stack comprises gate polysilicon, an oxide spacer, and a nitride sidewall spacer which covers the sidewalls of the gate polysilicon. A nitride cap, which is disposed between the nitride sidewall spacers, is formed on the gate polysilicon. The gate stack is defined only on the semiconductor substrate between the trenches.

The DRAM cell further includes a conductive space rail and a bit line contact. The bit line contact is aligned with the conductive space rail to expose both the nitride sidewall spacer and the semiconductor substrate. The conductive spacer rail is spaced from the bit line contact and is in contact with the gate polysilicon to run across the DRAM cell array.

However, this type of DRAM cell design is expensive to manufacture cost because of the complicated gate stack structure.

### SUMMARY OF THE PRESENT INVENTION

According to an embodiment of the present invention, there is provided a semiconductor device including a semiconductor substrate, a lower interconnection pattern formed on the semiconductor substrate, a lower interconnection spacer covering sidewalls of the lower interconnection pattern, spacer patterns disposed to cover the lower interconnection spacer, a first impurity region formed in the semiconductors substrate, and overlapping the lower interconnection pattern, a second impurity region overlapping the first impurity region, and aligned with the spacer pattern, an upper interconnection pattern disposed above the first and second impurity region.

According to another embosiment, there is provided a a method of manufacturing a semiconductor device by forming a lower interconnection pattern on a semiconductor substrate, forming a first impurity region to overlap the lower interconnection pattern, forming a lower interconnection spacer on sidewalls of the lower interconnection pattern, forming a buried layer to cover the first impurity region, the spacer pattern, and lower interconnection pattern, forming a node isolation layer on the buried layer, and forming a first photoresist pattern on the node isolation layer, spacer pattern, and lower interconnection pattern. The method further includes anisotropically etching the node isolation layer and the buried layer to form a connection hole to expose the first imputity region, isotropically etching the node isolation layer and the buried layer to expose the lower interconnection space and to form a plug hole, forming a spacer pattern to cover the lower interconnection spacer, forming a second impurity region to be aligned with the spacer pattern and to overlap the first impurity region, and forming an upper interconnection pattern above the first and second impurity regions.

### BRIEF DESCRIPTION OF THE DRAWINGS

Embodiments of the present invention will be readily apparent to those of ordinary skill in the art with the detailed description that follows when taken in conjunction with the accompanying drawings, in which like reference numerals denote like parts.

FIG. 1 is a layout showing a semiconductor device according to the present invention.

FIG. 2 is a cross-sectional view of a semiconductor device taken along line I-I′ of FIG. 1.

FIGS. 3 to 13 are cross-sectional views illustrating a method of forming a semiconductor device of the present invention.

### DETAILED DESCRIPTION OF THE PRESENT INVENTION

It will be understood that when an element such as a layer, region or substrate is referred to as being “on” or “onto” another element, the element is either directly on the other element or intervening elements may also be present.

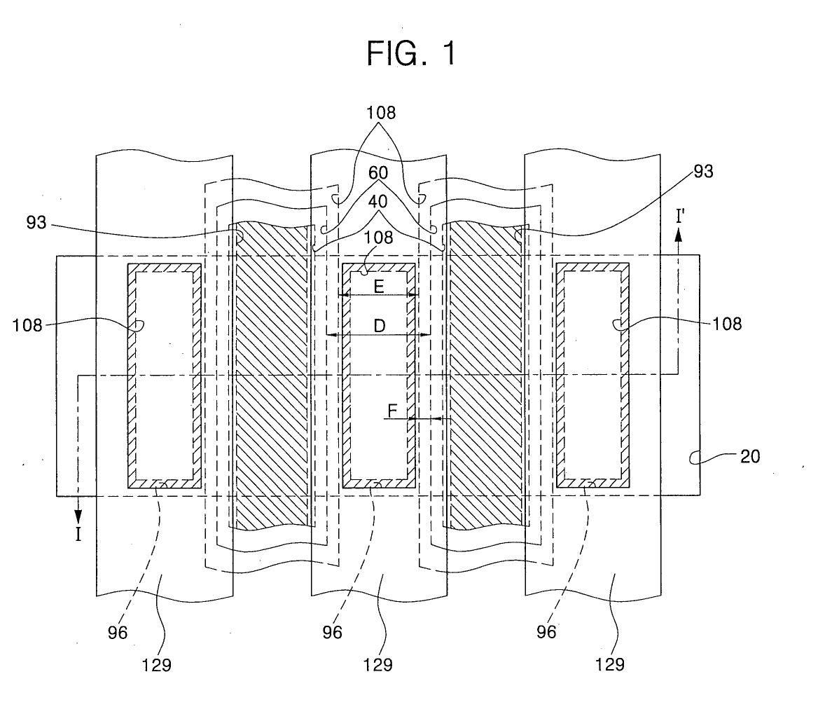

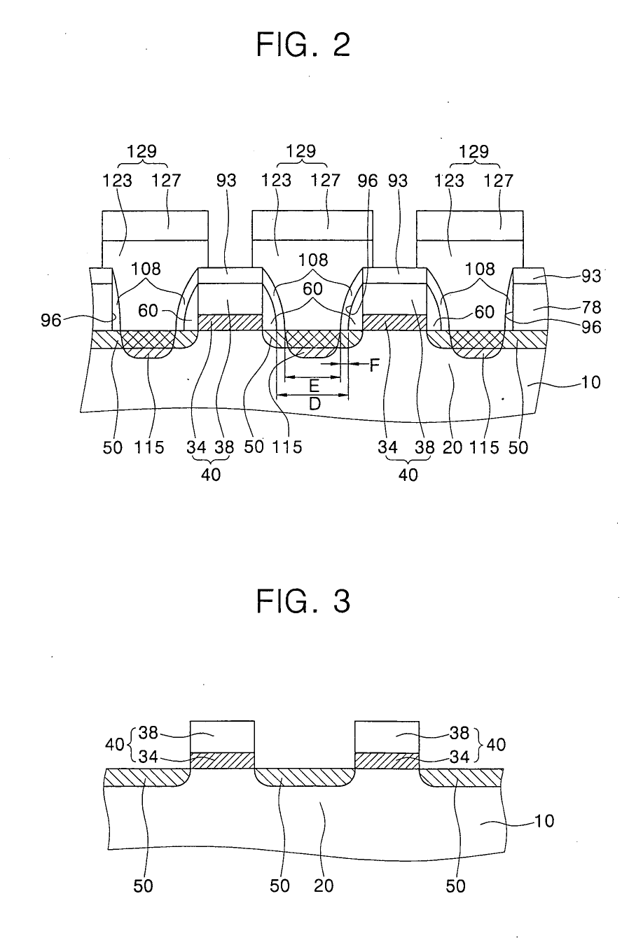

FIG. 1 is a semiconductor device layout illustrating the present invention, and FIG. 2 is a cross-sectional view taken along line I-I′ of FIG. 1.

Referring to FIGS. 1 and 2, first and second impurity regions 50 and 115 are disposed in an active region 20 on a semiconductor substrate 10. Second impurity region 115 overlaps first impurity region 50. First and second impurity regions (50, 115) preferably have the same type of dopants. The dopants are preferably N-type impurity ions. N-type impurity ions includes, for example, phosphor (P) or arsenic (As). The dopants may also be P-type impurity ions. P-type impurity ions includes, for example, boron (B) or boron fluoride (BF₂).

A lower interconnection pattern 40 is disposed on active region 20. Lower interconnection pattern 40 traverses active region 20. Lower interconnection pattern 40 includes a stacked lower interconnection layer 34 and lower interconnection capping layer 38. Lower interconnection capping layer 38 is preferably silicon nitride (Si₃N₄). Lower interconnection layer 34 is preferably formed of a stacked doped polysilicon and tungsten silicide (WSi). Lower interconnection layer 34 is preferably a gate.

A lower interconnection spacer 60 is disposed on sidewalls of lower interconnection pattern 40 and above first impurity region 50. Lower interconnection spacer 60 exposes a surface of semiconductor substrate 10 by a predetermined length (D). Lower interconnection spacer 60 is preferably an insulating layer having the same etching ratio as that of lower interconnection capping layer 38. Lower interconnection spacer 60 is preferably formed of silicon nitride. A spacer pattern 108 is disposed to cover lower interconnection spacer 60 and semiconductor substrate 10. Spacer pattern 108 is disposed between lower interconnection spacer 60 to expose the surface of semiconductor substrate 10 by a predetermined length (E). At the same time, spacer pattern 108 is preferably disposed to cover sidewalls of a plug hole 96. Spacer pattern 108 is preferably an insulating layer having the same etching ratio as that of lower interconnection spacer 60. Spacer pattern 108 is preferably formed of silicon nitride.

An upper interconnection pattern 129 is disposed on spacer pattern 108 and lower interconnection pattern 40. Accordingly, upper interconnection pattern 129 is disposed parallel to lower interconnection pattern 40. Upper interconnection pattern 129 is in contact with first and second impurity regions 50 and 115. Upper interconnection pattern 129 includes a stacked upper interconnection layer 123 and upper interconnection capping layer 127. Upper interconnection capping layer 127 is preferably an insulating layer having the same etching ratio as that of lower interconnection capping layer 34. Upper interconnection capping layer 127 is preferably formed of silicon nitride. Upper interconnection layer 123 is preferably formed of a stacked titanium nitride (TiN) and tungsten (W). Upper interconnection layer 123 may also be a stacked doped polysilicon and tungsten silicide (WSi). Upper interconnection layer 123 is preferably a bit line.

A buried layer 78 is disposed at one side of lower interconnection pattern 40. A node isolation layer 93 is disposed between buried layer 78 and upper interconnection pattern 129. Spacer pattern 108 is in contact at a side of buried layer 78 and node isolation layer 93. Buried layer 78 is preferably an insulating layer having an etching ratio different from that of node isolation layer 93. Node isolation layer pattern 93 is preferably an insulating layer, and may have an etching ratio different from that of lower interconnection capping layer 38. Buried layer 78 and node isolation layer 93 are silicon oxide (SiO₂). First impurity region 50 is disposed between two lower interconnection patterns 40, and between buried layer 78 and lower interconnection pattern 40. First impurity region 50 overlaps lower interconnection pattern 40, lower interconnection spacer 60, and spacer pattern 108.

Upper and lower interconnection patterns 129 and 40, impurity regions 50 and 115, lower interconnection spacer 60, and spacer pattern 108 comprise a transistor. First and second impurity regions 50 and 115 are preferably source and drain regions of the transistor. Spacer pattern 108 serves to prevent dopants of second impurity region 115 from diffusing into lower interconnection pattern 40. In addition, spacer pattern 108 serves to suppress by thickness (F) bulk diffusion of dopants of first impurity region 50. Accordingly, spacer pattern 108 allows first and second impurity regions 50 and 115 to uniformly overlap lower interconnection pattern 40 over the entire surface of semiconductor substrate 10 to enhance the electrical characteristics of the transistors.

Hereinafter, methods of forming semiconductor devices according to the present invention will be described.

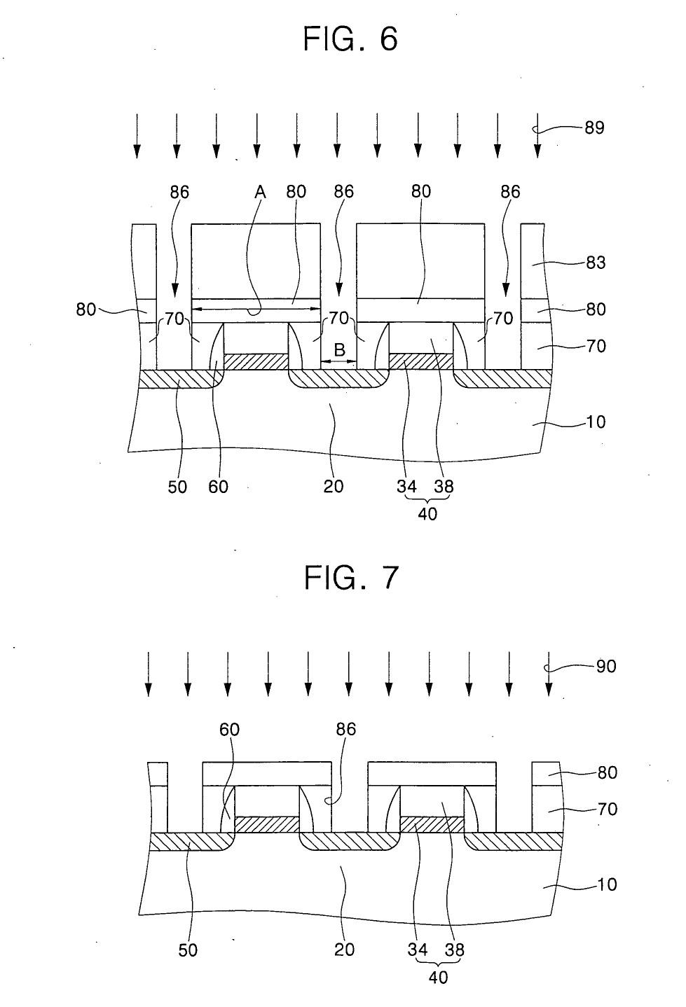

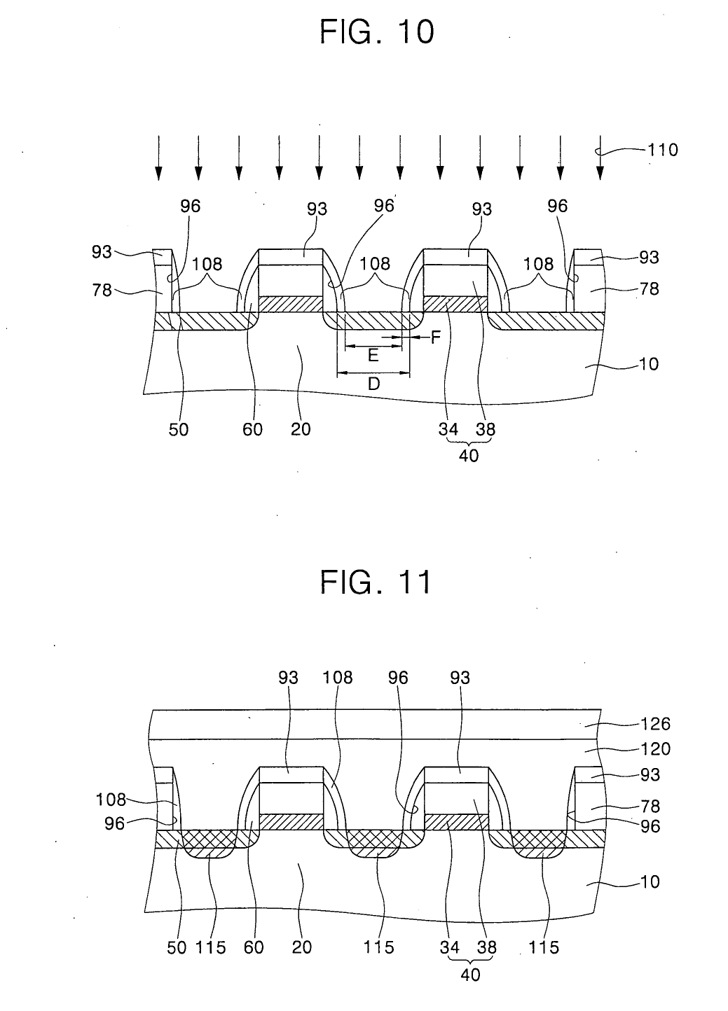

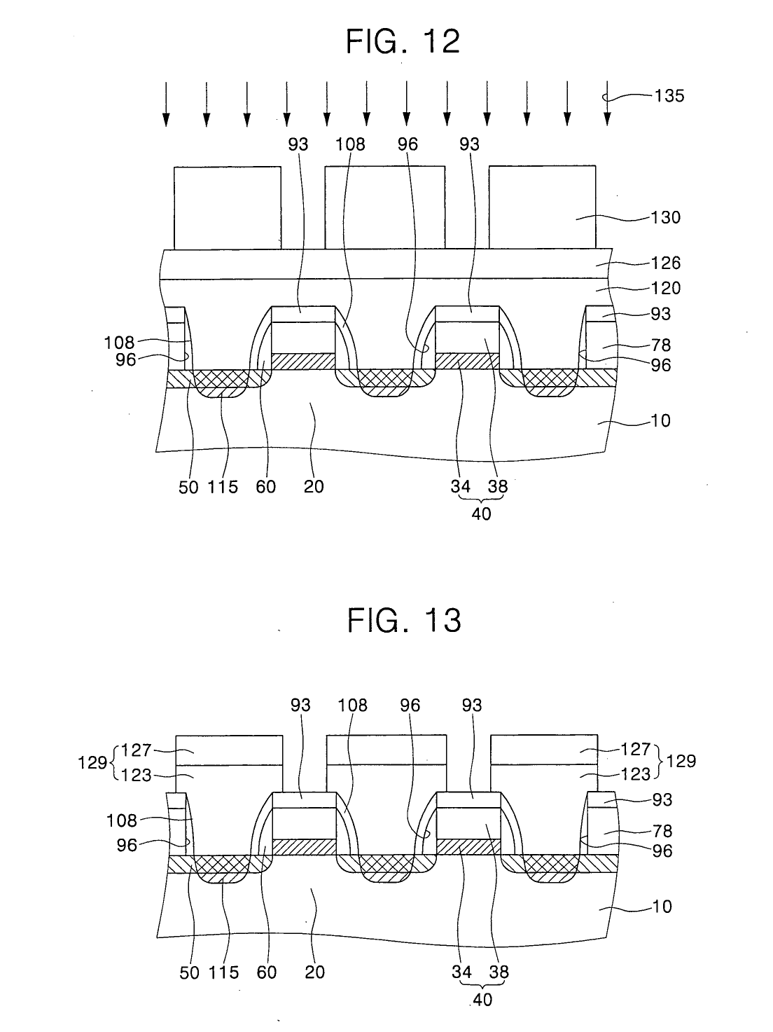

FIGS. 3 to 13 are cross-sectional views illustrating a method of forming a semiconductor device taken along line I-I′ of FIG. 1.

Referring to FIGS. 1, 3 to 5, a lower interconnection pattern 40 is formed on a semiconductor substrate 10. Lower interconnection pattern 40 is formed to traverse an active region 20. Lower interconnection pattern 40 includes a stacked lower interconnection layer 34 and lower interconnection capping layer 38. Lower interconnection capping layer 38 is preferably formed of silicon nitride (Si₃N₄). Lower interconnection layer 34 is preferably formed of a stacked doped polysilicon and Wsi. Lower interconnection layer 34 is preferably used as a gate.

A first impurity region 50 is formed in semiconductor substrate 10 to overlap lower interconnection patterns 40. First impurity region 50 is formed by doping with a conductivity type impurity. The dopants are preferably N-type, for example, P or As atoms. The dopants may also be P-type impurity ions, for example, B or BF₂ atoms.

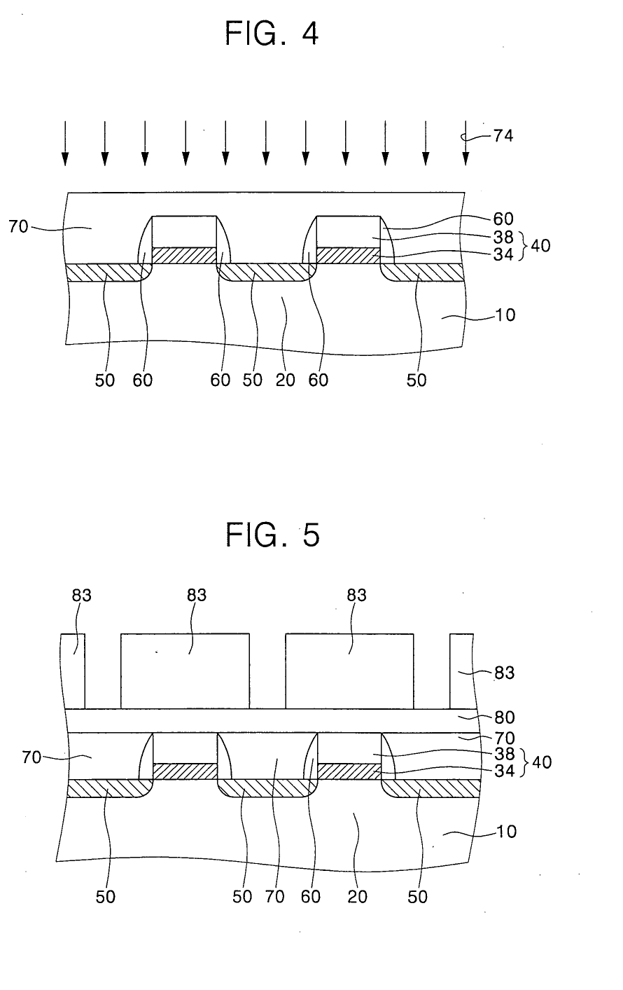

In FIG. 4, a lower interconnection spacer 60 is formed on sidewalls of lower interconnection pattern 40. Lower interconnection spacer 60 is preferably formed of an insulating layer having the same etching ratio as lower interconnection capping layer 38. Lower interconnection spacer 60 is formed of silicon nitride. Subsequently, a buried layer 70 is formed to cover lower interconnection patterns 40 and lower interconnection spacer 60. Then a planarization process 74 is performed on buried layer 70. Planarization process 74 is preferably formed to expose lower interconnection patterns 40. Planarization process 74 is preferably chemical mechanical polishing (CMP) or an etch-back process.

In FIG. 5, a node isolation layer 80 is formed to cover buried layer 70 and lower interconnection patterns 40. A photoresist pattern 83 is then formed on node isolation layer 80. Photoresist pattern 83 is formed to expose portions of node isolation layer 80.

Referring to FIGS. 1, 6 to 8, an anisotropic etching process 89 is performed on node isolation layer 80 and buried layer 70, using photoresist patterns 83 as an etching mask. Anisotropic etching process 89 forms a connection hole 86, which penetrates through node isolation layer 80 and buried layer 70 to expose first impurity region 50. Node isolation layer 80 between two connection holes 86 has a predetermined length (A). Connection hole 86 is preferably formed to have predetermined width (B). Connection holes 86 expose first impurity region 50. After forming connection hole 86, photoresist pattern 83 is removed from semiconductor substrate 10.

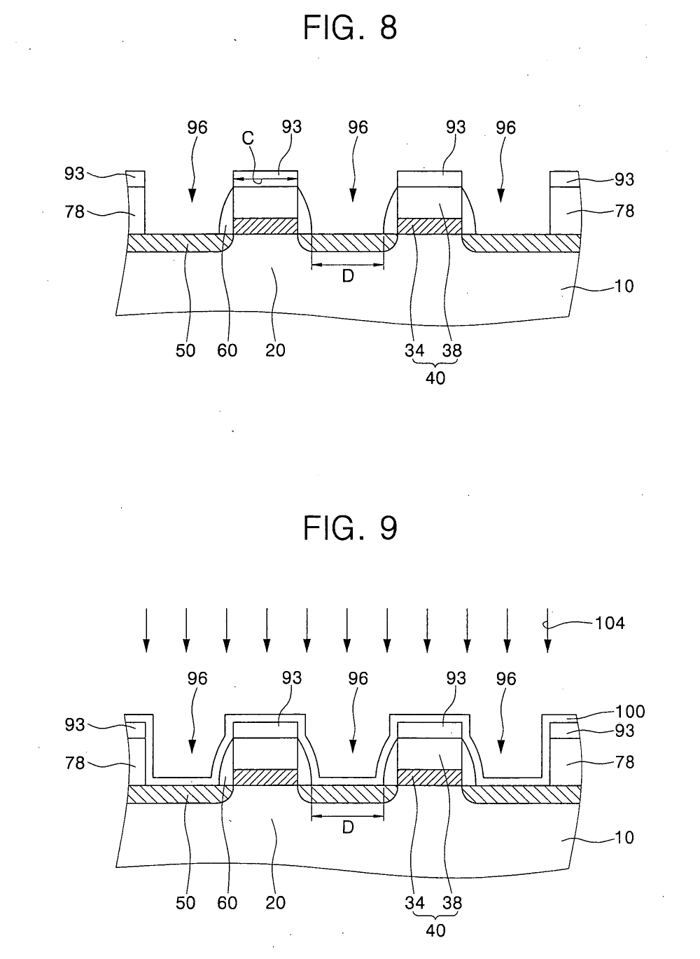

In FIGS. 7 and 8, an isotropic etching process 90 is performed on node isolation layer 80 and buried layer 70. Isotropic etching process 90 removes buried layer 70 in contact with lower interconnection spacer 60 and also forms a node isolation layer 93 on lower interconnection pattern 40. Furthermore, isotropic etching process 90 simultaneously forms a buried layer 78. Buried layer 78 is preferably formed of an insulating layer, and may have an etching ratio different from that of node isolation layer 93. Node isolation layer 93 is preferably formed of an insulating layer having an etching ratio different from that of lower interconnection capping layer 38. Node isolation layer 93 and buried layer 78 are preferably formed of silicon oxide. A plug hole 96 is formed to expose lower interconnection spacers 60 and impurity region 50. Node isolation layer 93 has a predetermined length (C). Predetermined length (C) may be adjusted within a tolerance range based on the semiconductor manufacturing process or a drivability range of the semiconductor device. Plug hole 96 preferably exposes impurity region 50 by a predetermined size (D) between lower interconnection patterns 40.

Referring to FIGS. 1, 9 and 10, a spacer layer 100 is formed to conformally cover plug hole 96 and node isolation 93. An anisotropic etching process 104 is performed on spacer layer 100 to form a spacer pattern 108. Spacer pattern 108 is preferably formed to expose first impurity region 50 between two lower interconnection patterns 40 by a predetermined length (E). A portion of spacer pattern 108 is formed to cover lower interconnection spacer 60, and a portion of spacer pattern 108 is in contact with node isolation layer 93. Spacer pattern 108 covers sidewalls of plug hole 96.

An implantation process 110 is preformed on semiconductor substrate 10 by using spacer patterns 108 and node isolation layers 93 as a mask. Implantation process 110 forms a second impurity region 115. Second impurity region 115 is formed to overlap impurity region 50. Second impurity region 115 is formed to have dopants of the same conductivity type as that of first impurity region 50. The dopants are preferably formed of N-type impurity ions. N-type impurity ions include, for example, P or As. The dopants may also be formed by P-type impurity ions. P-type impurity ions include, for example, B or BF₂. Second impurity region 115 is formed by using spacer pattern 108 as a mask to prevent second impurity region 115 from overlapping lower interconnection pattern 40 across the entire surface of first impurity region 50. Accordingly, second impurity region 115 is uniformly formed to be spaced from two lower interconnection patterns 40 by a predetermined distance. In addition, spacer pattern 108 covering lower interconnection spacer 60 by a thickness (F) prevents bulk diffusion of dopants from first impurity region 50. Impurity regions 50 and 115 are preferably used as source and drain regions of a transistor.

Referring to FIGS. 1, 11 to 13, an upper interconnection layer 120 and an upper interconnection capping layer 126 are preferably formed to cover spacer patterns 108 and node isolation layer 93. A photoresist pattern 130 is then formed on upper interconnection capping layer 126. Photoresist pattern 130 is formed to expose portions of upper interconnection capping layer 126. Photoresist pattern 130 is preferably formed to overlap node isolation layer 93.

An anisotropic etching process 135 is performed on upper interconnection capping layer 126 and upper interconnection layer 120 by using photoresist patterns 130 as an etching mask. Anisotropic etching process 135 forms an upper interconnection pattern 129 to be in contact with first and second impurity regions 50 and 115. Upper interconnection pattern 129 is formed parallel to the lower interconnection patterns 40 above semiconductor substrate 10. Upper interconnection pattern 129 includes a stacked upper interconnection 123 and upper interconnection capping layer 127. Upper interconnection capping layer 127 is preferably formed of an insulating layer having the same etching ratio as that of lower interconnection capping layer 38. Upper interconnection capping layer 127 is preferably formed of silicon nitride. Upper interconnection 123 is preferably formed of a stacked titanium nitride (TiN) and tungsten (W). Upper interconnection 123 may also be formed by stacking doped polysilicon and tungsten silicide (WSi). Upper interconnection 123 is preferably used as a bit line. After forming upper interconnection pattern 129, photoresist patterns 130 are removed from semiconductor substrate 10.

In another embodiment, anisotropic etching process 135 is not performed. To this end, upper interconnection layer 120 is formed to cover spacer pattern 108 and node isolation layer 93 as shown in FIG. 11. Upper interconnection layer 120 is preferably formed of a stacked titanium nitride (TiN) and tungsten (W). A planarization process is performed on upper interconnection layer 120 by using node isolation layer 93 as an etching buffer layer. The planarization process exposes node isolation layer 93 to form an upper interconnection between spacer patterns 108. After performing the planarization process, a conductive layer interconnection is preferably formed on the upper interconnection.

Upper interconnection and lower interconnection patterns 129 and 40, lower interconnection spacer 60, spacer pattern 108, and impurity regions 50 and 115 comprises a transistor.

As described above, the present invention discloses a spacer pattern covering a lower interconnection spacer and allowing a second impurity region not to overlap a lower interconnection pattern. Therefore, a spacer pattern is uniformly formed to be spaced by a predetermined distance from the lower interconnection pattern to enhance the electrical characteristics of a transistor.

What is claimed is:

1. A semiconductor device, comprising:
a semiconductor substrate;
a lower interconnection pattern formed on the semiconductor substrate;
a lower interconnection spacer covering sidewalls of the lower interconnection pattern;
spacer patterns disposed to cover the lower interconnection spacer;
a first impurity region formed in the semiconductore substrate, and overlapping the lower interconnection pattern;
a second impurity region overlapping the first impurity region, and aligned with the spacer pattern;
an upper interconnection pattern disposed above the first and second impurity region.

2. The semiconductor device of claim 1, further comprising a node isolation layer interposed between the lower interconnection pattern and the upper interconnection pattern.

3. The semcondcutor device of claim 1, wherein the lower interconnection pattern comprises a lower interconnection layer and a lower interconnection capping layer.

4. The semiconductor device of claim 1, wherein the upper interconnection pattern comprises an upper interconnection layer and an upper interconnection capping layer.

5. The semiconductor device of claim 3, wherein the lower connection layer is a stacked doped polysilicon and tungsten silicide, and the lower intercommection capping layer is silicon nitride.

6. The semiconductor device of claim 4, wherein the upper interconnection layer is formed of a stacked titanium nitride and tungsten layer, or a stacked doped polysilicon and tungsten silicide layer.

7. The semiconductor device of claim 2, wherein the node isolation layer is an insulating layer having an etching ratio different from that of the lower interconnection capping layer.

8. The semiconductor device of claim 3, wherein the spacer pattern is formed of an insulating layer having the same etching ratio as that of the lower interconnection capping layer.

9. The semiconductor device of claim 3, wherein the lower interconnection layer is a gate.

10. The semiconductor device of claim 4, wherein the upper interconnection layer is a bit line.

11. A method of manufacturing a semiconductor device, comprising:
forming a lower interconnection pattern on a semiconductor substrate;
forming a first impurity region to overlap the lower interconnection pattern;
forming a lower interconnection spacer on sidewalls of the lower interconnection pattern;
forming a buried layer to cover the first impurity region, the spacer pattern, and lower interconnection pattern;
forming a node isolation layer on the buried layer;
forming a first photoresist pattern on the node isolation layer, spacer pattern, and lower interconnection pattern;
anisotropically etching the node isolation layer and the buried layer to form a connection hole to expose the first imputity region;
isotropically etching the node isolation layer and the buried layer to expose the lower interconnection spacer and to form a plug hole;
forming a spacer pattern to cover the lower interconnection spacer;
forming a second impurity region to be aligned with the spacer pattern and to overlap the first impurity region; and
forming an upper interconnection pattern above the first and second impurity regions.

12. The method of claim 11, wherein forming the upper interconnection pattern comprises;
forming an upper interconnection layer and an upper interconnection capping layer on the plug hole, the spacer pattern, and first and second impurity regions;
forming a second photoresist pattern on the upper interconnection capping layer; and
performing an anisotropic etch to form the upper interconnection pattern.

13. The method of claim 11, wherein the lower interconnection pattern comprises a lower interconnection layer and a lower interconnection capping layer.

14. The method of claim 13, wherein the lower connection layer is a stacked doped polysilicon and tungsten silicide, and the lower interconnection capping layer is silicon nitride.

15. The method of claim 12, wherein the upper interconnection layer is formed of a stacked titanium nitride and tungsten layer or a stacked doped polysilicon and tungsten silicide layer.

16. The method of claim 11, wherein the buried layer is formed of an insulating layer having an etching ratio different from that of the node isolation layer.

17. The method of claim 13, wherein the node isolation layer is formed of an insulating layer having an etching ratio different from that of the lower interconnection capping layer.

18. The method of claim 13, wherein the spacer pattern is formed of an insulating layer having the same etching ratio as that of the lower interconnection capping layer.

19. The method of claim 12, wherein the upper interconnection layer is a bit line.

20. The method of claim 13, wherein the lower interconnection layer is a gate.
